(19) United States
(12) Patent Application Publication
(10) Pub. No.: US 2025/0096512 A1
(43) Pub. Date: Mar. 20, 2025

(54) PORT ENTRY CONNECTOR

(71) Applicant: CommScope Technologies LLC, Hickory, NC (US)

(72) Inventors: Jinwoo LEE, Souderton, PA (US); Reza SAEDI, Bryn Mawr, PA (US)

(73) Assignee: CommScope Technologies LLC, Hickory, NC (US)

(21) Appl. No.: 18/293,297

(22) PCT Filed: Jul. 26, 2022
(86) PCT No.: PCT/US2022/038304

§ 371 Date: Jan. 29, 2024

Related U.S. Application Data
(60) Provisional application No. 63/226,629, filed on Jul. 28, 2021.

(51) Int. Cl. H01R 24/50

(52) U.S. Cl. CPC H01R 24/50

(57) ABSTRACT

A coaxial connection device for a male coaxial connector, in the form of a stinger, resides within a housing. The housing has a port with a cylindrical wall with a conductive inner thread. The stinger has a conductive outer thread, sized to mate with the inner thread. A center conductor of the male connector enters a hole within the port. A circuit board within the housing supports a tube-like receiving chamber with an opening to receive the center conductor. The receiving chamber has a frictional member to establish an electrical connection with a sidewall of the center conductor. An insulation material surrounds the receiving chamber. A shield surrounds the insulation material. An RF tab is attached to the frictional member and communicates signals from the center conductor to elements of the circuit board. A ground tab is attached to the shield and grounds the shield to a ground plane of the circuit board.

### CROSS-REFERENCE TO RELATED APPLICATIONS

The present application is a 371 National Stage Patent Application claiming priority to PCT International Patent Application No. PCT/US22/38304 filed Jul. 26, 2022, which claims the benefit of U.S. Provisional Patent Application No. 63/226,629 filed Jul. 28, 2021 the contents of which are each incorporated herein by reference in their entirety.

### FIELD OF THE INVENTION

The present invention relates to a port for receiving a coaxial connector. More particularly, the present invention relates to a circuit board device with a receiving chamber to establish electrical contact with a center conductor of a male coaxial connector of the type commonly referred to as a stinger.

### DESCRIPTION OF THE RELATED ART

In wired communication services, such as CATV, Internet and phone services, communication signals are commonly carried along overhead coaxial cables along roadways via utility poles. These long spans of coaxial cable are usually referred to as trunk or distribution cables, having large outer diameters such as ½ inch or greater. Periodically, the trunk cable is terminated to a first connector, and the first connector is mated to a first through port of a drop unit. The drop unit has plural drop ports and a second through port which mates to a second connector attached to a further strand of trunk cable.

The drop ports mate with connectors attached to a smaller diameter coaxial cable, such as RG6, which smaller cable extends to a customer's residence or a place of business, to provide Internet, phone service, and/or entertainment services, e.g., CATV services. In practice, dozens to hundreds of drop units are located throughout neighborhoods, and trunk cables are interconnected between the drop units.

The trunk cables may also be terminated to a conversion unit, including optical-to-electrical converters and electrical-to-optical converters, in the case of a hybrid-fiber-coax (HFC) system. Also, trunk cables may be terminated to upstream and downstream sides of amplifier units to boast the RF signal carried by the trunk cables. Such drop units, amplifiers and conversion units, as well as other units, like inline filters and surge arrestors, with ports to receive a connector of a trunk cable will be collectively referred to as ported cable devices.

ANSI/SCTE 92 2017 is a publication by the American National Standard Institute/Society of Cable Telecommunications Engineers and describes a standard for a male plug suitable for use on coaxial trunk cables, which standard is herein incorporated by reference. In general, the male plug has a threaded ⅝-24 engagement part suited to seat into a female ⅝-24 equipment port.

FIG. 1 is derived from the single view provided in the seven pages of the ANSI/SCTE 92 2017 standard. FIG. 1 shows a mating end 13 of a male connector 11 in accordance with the prior art of ANSI/SCTE 92 2017. The mating end 13 has a threaded ⅝-24 engagement part 15, meaning a diameter D1 of the engagement part 15 is about 0.625 inches and there are twenty-four threads 17 per inch in a direction parallel to a central axis CA of the male connector 11. A landing 19 is formed on a cable receiving side 21 of the engagement part 15. The landing 19 has a second diameter D2 of about 0.529 to 0.545 inches and a length (parallel to the central axis CA) of about 0.071 to 0.100 inches. The landing 19 receives an O-ring 23 (shown in cross section to simplify the drawing). The O-ring 23 is bordered by a shoulder 25 on the cable receiving side 21 of the male connector 11. The shoulder 25 has a diameter D3 of about 0.740 to 1.000 inches.

A tool surface 27, such as a hexagonal nut, resides on the cable receiving side 21 of the shoulder 25. The tool surface 27 is used to screw the outer threads 17 into inner threads 39 of a port 37 (best seen in FIG. 3). The outer diameter and shape of the tool surface 27 is not defined by the standard. However, a length L1 from a forward face 29 of the tool surface 27 to a forward face 31 of the engagement part 15 should be 0.290 to 0.370 inches. Also, a length L2 from the forward face 29 of the tool surface 27 to a tip end 33 of a center conductor 35 should be 2.115 to 2.440 inches.

The cable receiving side 21 of the male connector 11 is not dictated by the standard and may take several forms. The center conductor 35 may be a part of a coaxial cable, such as a seventy-five ohm trunk or distribution cable, having an outer diameter of about ½ inch. The jacket, shielding layers, and inner dielectric are stripped free from a few inches at the end of the cable to expose the center conductor of the cable. Then, the prepared end is mounted directly into the male connector 11 such that the center conductor 35 of the cable becomes the center conductor 35 of the male connector 11.

Alternatively, the male connector 11 may take the form of an adapter and the center conductor 35 may be a fixture of the male connector 11. A female coaxial connector may be formed on the cable receiving side 21 of the male connector 11. The female coaxial connector of the male connector 11 is mated to a termination of a trunk cable. FIGS. 20 and 21 of U.S. Pat. No. 9,490,592, which is herein incorporated by reference, shows a design wherein a male connector 11 is formed as an adapter, similar to the configuration just described. As noted in the '592 Patent, the outer thread 17 of the mating end 13 of a male connector 11 in combination with the two inches of exposed center conductor 35 resembles a bee stinger, and hence the term “stinger” has been commonly applied to the configuration shown in Prior Art FIG. 1.

FIG. 2 is a perspective view of a port entrance area within a weather-tight housing 41, and FIG. 3 is a cross sectional view taken along line III-III in FIG. 2. A female port 37 to receive the male connector 11 has inner thread 39 of the ⅝-24 type to seat the external thread 17 of the male connector 11. The male connector 11 is screwed into the port 37 until the O-ring 23 forms a weather-tight seal with a ledge with port 37, so as to keep the housing 41 weather-tight.

The center conductor 35 extends into the housing 41 of the ported cable device and resets upon a conductive surface 43, e.g., an anvil, which has legs which are electrically connected to conductive traces on a circuit board 45. The conductive traces lead to filters, surge arrestors, amplifiers, splitters, E/O convertors, etc. on the circuit board 45.

To maintain good electrical contact between the center conductor 35 and the conductive surface 43, e.g., anvil, a technician opens the housing 41 and engages a first end 47 of a threaded fastener 49 with a tool, e.g., an Allen key in the case of FIG. 3. Rotation of the threaded fastener 49 drives the second end 51 of the threaded fastener 49 into contact with the center conductor 35, which sandwiches the center conductor 35 between the second end 51 of the threaded fastener 49 and the conductive surface 43, e.g., anvil, under a pressure defined by the torque applied to the threaded fastener 49.

The threaded fastener 49 is typically located within a shielding box 53. To access the threaded fastener 49, a technician must open the weather-tight housing 41, and open the shielding box 53, which may be secured by a one or more screws 54. Alternatively, an opening 55 may be provided in the shielding box 53 to access the threaded fastener 49 with the end of the tool, e.g., an Allen key. Further, examples of similar arrangements, wherein a threaded fastener is used to seize the center conductor 35 of the male connector 11, e.g., the stinger, are shown in U.S. Pat. Nos. 6,129,597; 6,390,829; 7,318,756 and 7,625,247, which are herein incorporated by reference.

U.S. Pat. No. 7,669,323, which is herein incorporated by reference, appreciated several problems with the prior art described above. First, the housing of the ported cable device has to be opened to access the first end of the threaded fastener. This allows the environmental elements to enter the housing, e.g., it may be raining or dusty outside when the housing of the ported cable device is opened to secure the center conductor of the stinger. Second, the technician needs to carry a torque measuring device, so as to not over-torque the threaded fastener and deform/damage the center conductor of the stinger.

To address these issues, U.S. Pat. No. 7,669,323 provides access to the first ends of the threaded fasteners on the outside of the housing, so that the housing does not need to be opened to seize the center conductor of the stinger to the conductive anvil within the housing. Also, there is a spring-loaded plunger element between the first and second ends of the threaded fastener. The plunger allows the compression force sandwiching the center conductor between the conductive anvil and the second end of the threaded fastener to remain substantially constant, as the threaded fastener is rotated to move toward the center conductor.

### SUMMARY OF THE INVENTION

The Applicant has discovered drawbacks with the ports of the prior art. It is an object of the present invention improve upon the ports of the prior art, and more specifically, to provide a receiving chamber with a friction member within the port to establish electrical contact with the center conductor of the stinger.

As with U.S. Pat. No. 7,669,323, the present invention provides a solution wherein the technician does not need to carry a torque measuring tool in order establish a good electrical connection to the center conductor. Also, the housing does not need to be opened to establish an electrical connection between the center connector and the elements within the housing.

One drawback to the solution of U.S. Pat. No. 7,669,323 was that the threaded fasteners penetrated the housing. Hence, in order to keep the housing weather-tight, a sealing system, would need to be added for each threaded fastener, which corresponds to the number of stringer ports. Adding extra O-rings or gaskets for each threaded fastener adds more potential failure points to the housing to allow water to enter the housing and damage the electrical elements therein.

It is an object of the present invention to provide a device within the housing which will establish good and repeatable electrical contact with an inserted center conductor of a male connector, e.g., a stinger, without the need to open the housing or rotate any threaded fastener to adjust an engagement force with the center conductor.

These and other objects are accomplished by a coaxial connection device for a male coaxial connector, in the form of a stinger. The cable device resides within a housing. The housing has a port with a cylindrical wall with a conductive inner thread. The stinger has a conductive outer thread, sized to mate with the inner thread. A center conductor of the male connector enters a hole within the port. A circuit board within the housing supports a tube-like receiving chamber with an opening to receive the center conductor. The receiving chamber has a frictional member to establish an electrical connection with a sidewall of the center conductor. An insulation material surrounds the receiving chamber. A shield surrounds the insulation material. An RF tab is attached to the frictional member and communicates signals from the center conductor to elements of the circuit board. A ground tab is attached to the shield and grounds the shield to a ground plane of the circuit board.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limits of the present invention, and wherein:

FIG. 1 is a side view in partial cross-section showing a male connector, or stinger, in accordance with the prior art;

FIG. 2 is a perspective view of a port entrance area within a weather-tight housing;

FIG. 3 is a cross sectional view taken along line III-III in FIG. 2;

FIG. 4 is an exploded view of a circuit board device to capture a center conductor of a stinger;

FIG. 5 is a top, left side perspective view of the assembled circuit board device of FIG. 1;

FIG. 6 is a bottom, right side perspective view of the assembled circuit board device of FIG. 1;

FIG. 7 is a top, left side perspective view of the circuit board device mounted to a circuit board;

FIG. 8 is a top, left side perspective view of the circuit board of FIG. 7 mounted within a weather-tight housing;

FIG. 9 is a close-up view of a dashed circular area IX in FIG. 8;

FIG. 10 is a cross sectional view through a portion of FIG. 9, showing an alignment between the circuit board device and a port in the housing;

FIG. 11 is an exploded view of a first alternative embodiment of a receiving chamber for the circuit board device;

FIG. 12 is a top, left side perspective view of the receiving chamber of FIG. 11 when assembled;

FIG. 13 is a top, left side perspective view of a second alternative embodiment of a receiving chamber for the circuit board device; and

FIG. 14 is a front view of the receiving chamber of FIG. 13.

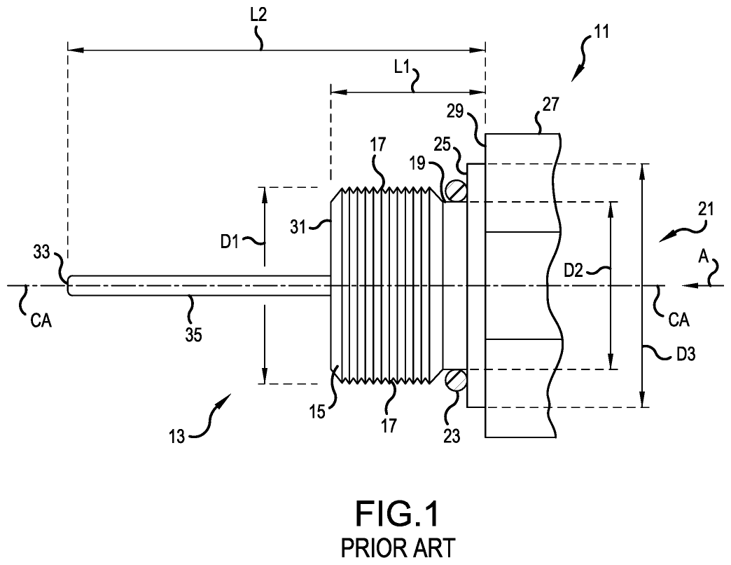

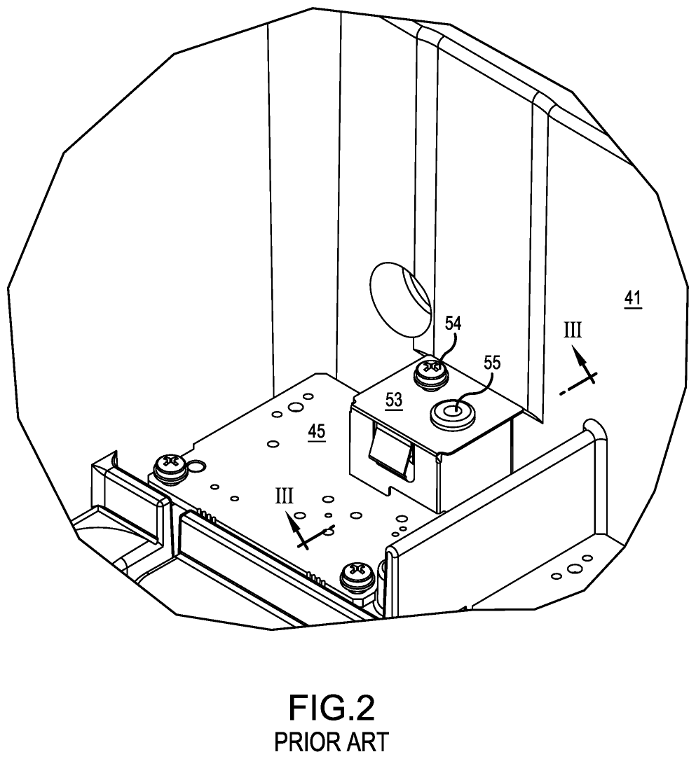

### DETAILED DESCRIPTION OF EMBODIMENTS OF THE INVENTION

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

Like numbers refer to like elements throughout. In the figures, the thickness of certain lines, layers, components, elements or features may be exaggerated for clarity. Broken lines illustrate optional features or operations unless specified otherwise.

The terminology used herein is for the purpose of describing particular embodiments only and is not intended to be limiting of the invention. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “lateral”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. The device may be otherwise oriented (rotated 90 degrees or at other orientations) and the descriptors of relative spatial relationships used herein interpreted accordingly.

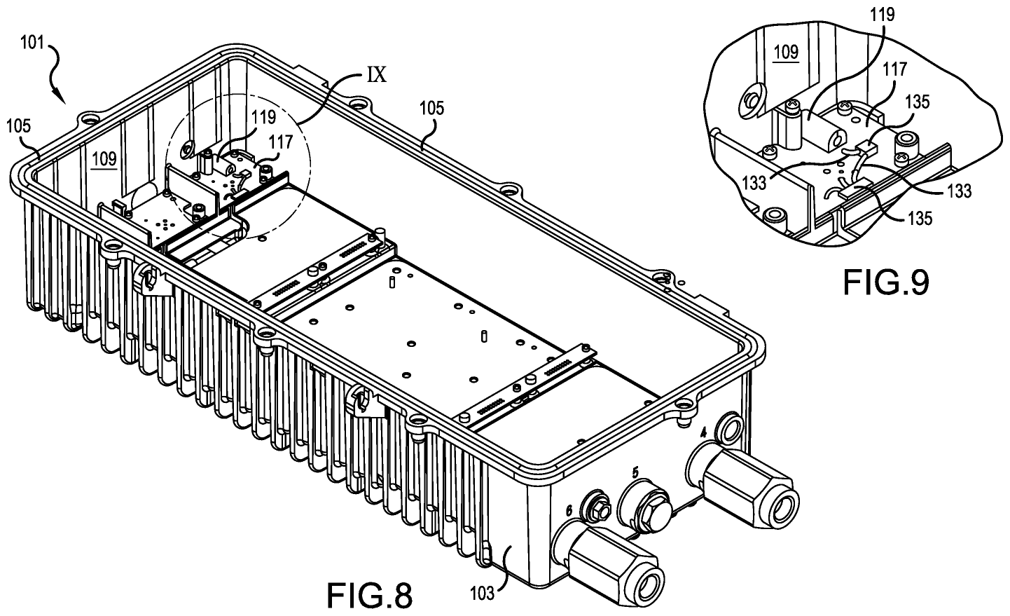

As best seen in FIG. 8 and the close-up view of FIG. 9, a ported cable device 101 includes an enclosed housing 103. FIG. 8 shows half of a “clam-shell” housing 103. Typically, a gasket 105 is provided between the two halves of the clam-shell housing 103 to make the housing 103 weather-tight, so that the housing 103 may be located outside, e.g., mounted to a pole or strand of overhead cable and/or messenger wire, while keeping an interior space of the housing 103 protected from the elements.

Weather-tight may be defined as structured such that water falling onto the housing 103, e.g., rainwater, will not enter the housing 103. Weather-tight is more generic, but fully encompasses water-tight. The housing 103 may also be upgraded to water-tight. In other words, if a water-tight housing 103 is held underwater, e.g., completely sub-merged beneath at least an inch of water, water will not leak into the housing 103. Deeper depths of water-tight ratings, such as water-tight to 30 meters, are common with housings for wrist watches and diver's gauges, but do not seem to be required of the housings 103 typically used in combination with overhead CATV coaxial cables.

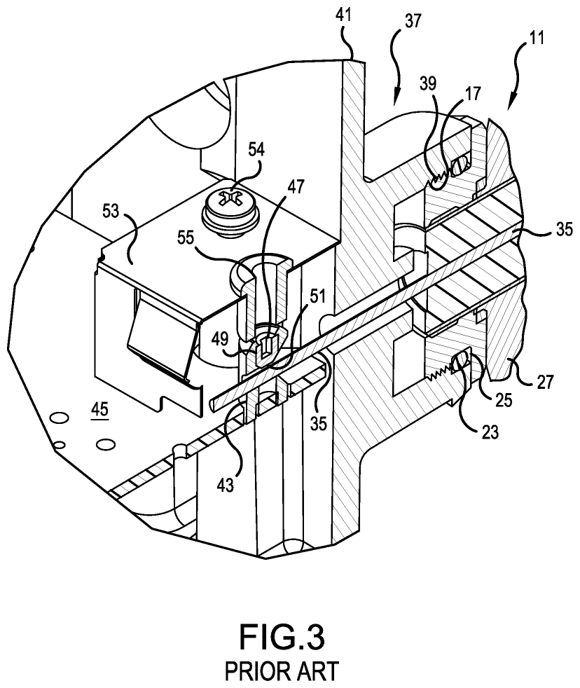

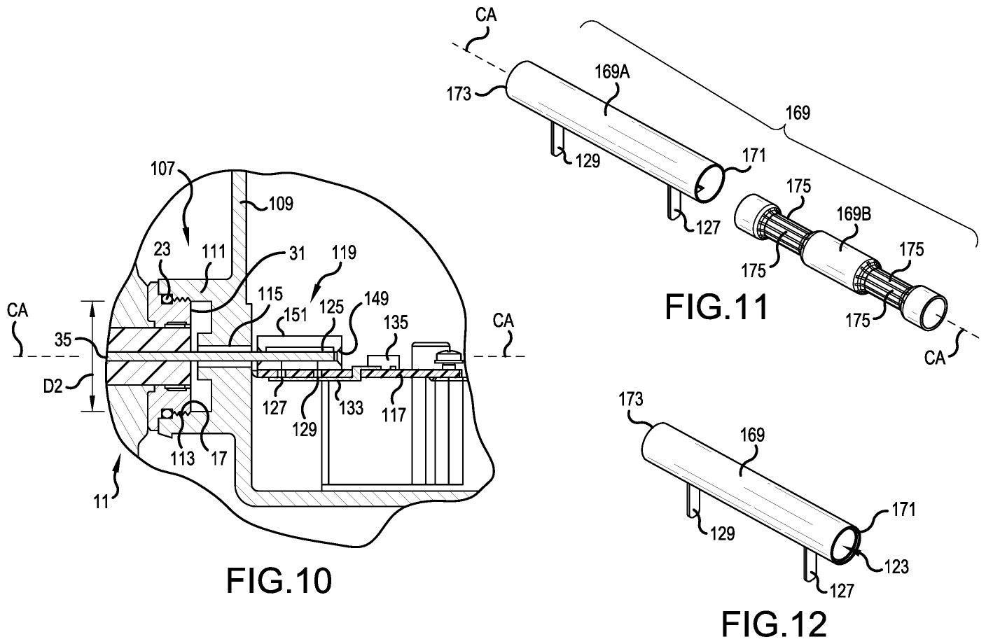

FIG. 10 is a cross-sectional view through a portion of FIG. 9, showing an alignment between a circuit board device 119 and a port 107 in the housing 103. The port 107 is formed in a side wall 109 of the housing 103. The port 107 has a first cylindrical wall 111. A conductive inner thread 113 is formed on an inner surface of the first cylindrical wall 111. A hole 115 communicates an environment exterior to the housing 103 with a space within the housing 103. The hole 115 within the port 107 is centered on a central axis CA of the first cylindrical wall 111 of the port 107. The first cylindrical wall 111 has an inner diameter D1 of about ⅝ inch, and the inner thread 113 is formed with a pitch of twenty-four threads per linear inch along a line parallel to the central axis CA. These features may be formed the same as the prior art features of FIG. 3, relating to the inner thread 39 of the female port 37.

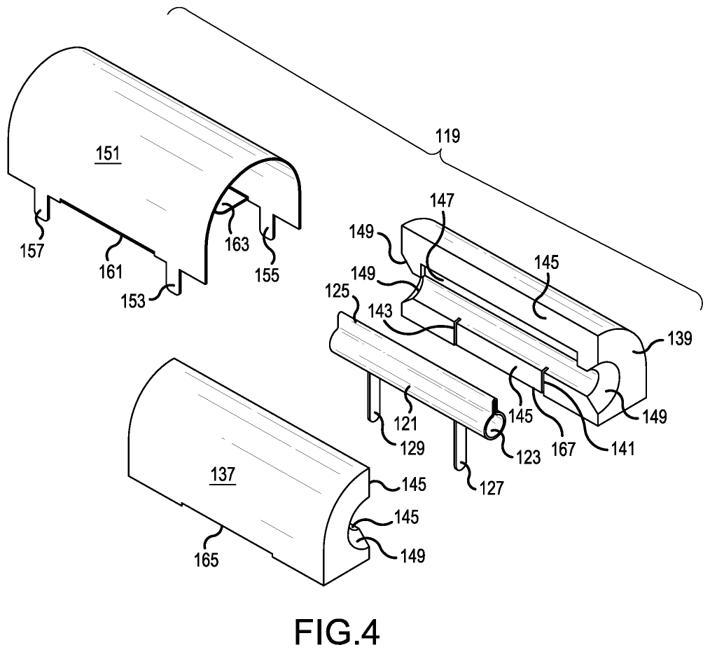

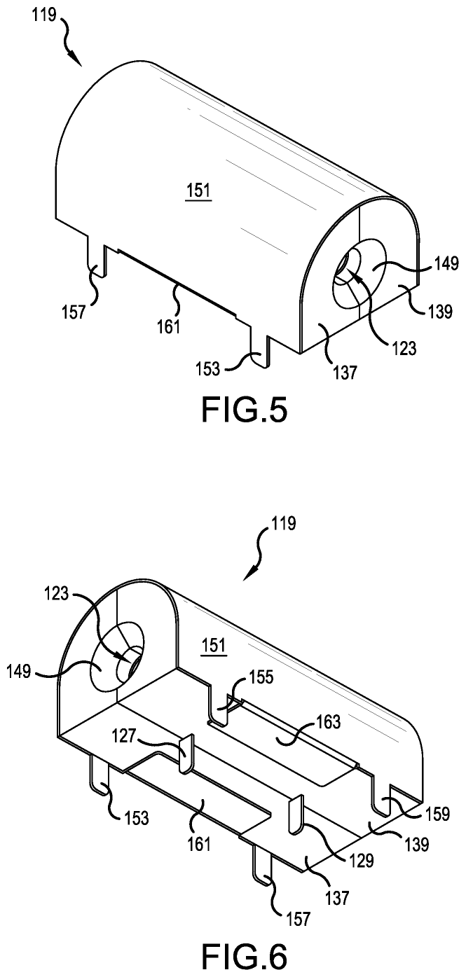

A mounting member, in the form of a circuit board 117, is attached to an interior of the housing 103 proximate the port 107. A circuit board device 119 is attached to the circuit board 117. As best seen in the views of FIGS. 4-6, the circuit board device 119 includes a tube-like receiving chamber 121. The tube-like shape of the receiving chamber 121 has a hollow core with an opening 123 formed at one end of the receiving chamber 121 aligned with the hole 115 within the port 107 to receive the center conductor 35 of the male coaxial connector 11, which is inserted through the hole 115. A cross sectional shape of the receiving chamber 121 is substantially circular, when view in a plane perpendicular to the central axis CA. The opposite end of the receiving chamber 121 may also be open, or may be closed, if desired.

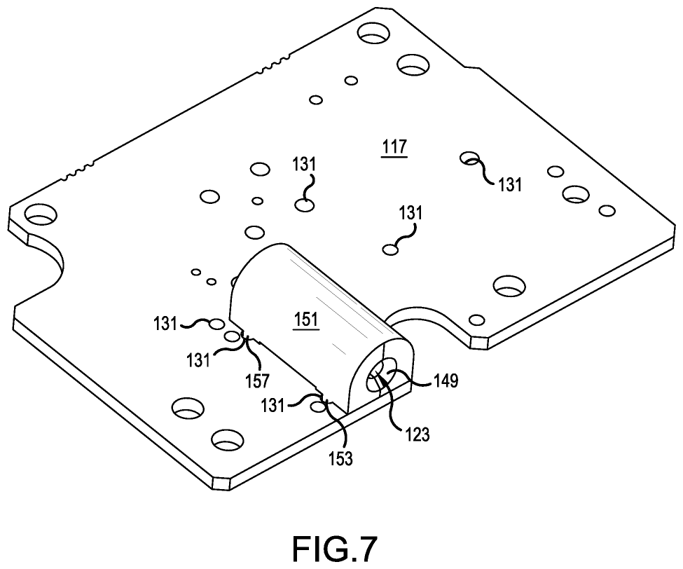

In the embodiment of FIGS. 4-10, the receiving chamber 121 has an expansion fold 125. The opening 123 of the receiving chamber 121 has a diameter which is slightly less than a diameter of the center conductor 35 of the male coaxial connector 11 to be inserted into the receiving chamber 121. The center conductor 35 expands the opening 123 of the receiving chamber 121 by expanding, e.g., partially opening, the expansion fold 125 so as to enlarge the cross section of the receiving chamber 121 and cause portions of inner sidewalls of the receiving chamber 121 to function as frictional members to frictionally engage, and establish electrical contact with, an outer surface of the center conductor 35.

A first RF tab 127 and a second RF tab 129 are electrically attached to the receiving chamber 121 and hence the sidewalls of the receiving chamber 121, which are in electrical contact with the center conductor 35. The first and second RF tabs 127 and 129 are preferably integrally formed with the receiving chamber 121, e.g., stamped and then bent outwardly from a single sheet of metal, which is also rolled to form the tube-like shape. The first and second RF tabs 127 and 129 are attached to the circuit board 117 by being passed through two of a plurality of through holes 131 formed in the circuit board 117 and are used to mechanically fix the receiving chamber 121 to the circuit board 117.

In a preferred embodiment, the receiving chamber 121 and the first and second RF tabs 127 and 129 are formed from a single sheet of conductive metal, like prosperous bronze with a tin plating or beryllium copper with a tin plating. However, other conductive metals and/or platings, such as a gold plating, may be substituted. Preferably, the conductive metal used has a resilience, like a spring, tending to return to its former shape and position when a slight deflection or deformation is placed upon the metal. This means that the expansion fold 125 will strongly and repeatably cause the inner sidewalls of the receiving chamber 121 to conductively engage the outer surface of the center conductor 35.

The first and second RF tabs 127 and 129 are also soldered to one or more conductive traces 133 on the circuit board 117. The conductive traces 133 lead to other circuit elements 135 mounted within through holes 131 of the circuit board 117. Such other circuit elements 135 may form a filter, surge arrestor, amplifier, splitter, combiner, electrical-to-optical convertor or similar structure.

An insulation material surrounds at least a portion of the receiving chamber 121. In the embodiment of FIGS. 4-10, the insulation material consists of first and second half shells 137 and 139, which mate to completely surround the receiving chamber 121. First and second slots 141 and 143 are formed in each of the first and second half shells 137 and 139. The first and second slots 141 and 143 receive the first and second RF tabs 127 and 129 and permit the lower and upper facing sides 145 of the first and second half shells 137 and 139 to abut in a flush fashion.

A rectangular indentation 147 is also formed in the first and second half shells 137 and 139 to hold the expansion fold 125. The rectangular indentation 147 is oversized so as to permit the expansion fold 125 to slightly open as the center conductor 35 is inserted into the opening 123 and passes further into the receiving chamber 121. A front of each of the first and second half shells 137 and 139 includes a conical shape 149 to guide the center conductor 35 of the male connector 11 into the opening 123 of the receiving chamber 121.

The first and second half shells 137 and 139 are formed of an insulation material, such as a plastic dielectric material, ceramic, glass, or any other known non-conductive material common to the electrical arts. Preferably, the first and second half shells 137 and 139 are identically formed by a single mold to save costs. The primary functions of the first and second half shells 137 and 139 are to guide the center conductor 35 of the male connector 11 into the opening 123 of the receiving chamber 121 and to space and electrically isolate the receiving chamber 121 from an electromagnetic shield 151.

The shield 151 surrounds at least a portion of the first and second half shells 137 and 139. In the embodiment of FIG. 4-10, the shield 151 completely surrounds the first and second half shells 137 and 139. The shield 151 is generally C-shaped and has plural ground tabs, such as first, second, third and fourth ground tabs 153, 155, 157 and 159 extending way from the ends of the C-shaped profile. The ground tabs 153, 155, 157 and 159 extend into through holes 131 of the circuit board 117 to mechanically secure the shield 151 to the circuit board 117 and also electrically connect the shield 151 to a ground plane of the circuit board 117.

First and second landing tabs 161 and 163 also extend away from the ends of the C-shaped profile of the shield 151, but are bent inwardly towards each other at about a ninety degree angle relative to the ends of the C-shaped profile. The landing tabs 161 and 163 engage into recessed pockets 165 and 167 formed on the bottoms of the first and second half shells 137 and 139. This engagement assists in keeping the elements of the circuit board device 119 together prior to the mounting of the circuit board device 119 onto the circuit board 117, e.g., the first and second half shells 137 and 139 with the receiving chamber 121 captured therein will not slide out of an end of the shield 151.

In a preferred embodiment, the shield 151 is formed from a single sheet of conductive metal, like prosperous bronze with a tin plating or beryllium copper with a tin plating. However, other conductive metals and/or platings, such as a gold plating, may be substituted. The primary functions of the shield 151 with its four grounding tabs 153, 155, 157 and 159 is to firmly secure the circuit board device 119 to the circuit board 117, so that the force of the center conductor 35 entering the opening 123 and the receiving chamber 121 does not break the circuit board device 119 free from the circuit board 117. Also, the four grounding tabs 153, 155, 157 and 159 electrically connect the shield 15 to a ground plane of the circuit board 117, which is typically connected to the housing 103. Grounding the shield 151 will assist in reducing any electromagnetic interference (EMI) from exiting the center conductor 35 and polluting the interior of the housing 103, and also prevent EMI from exiting the interior of the housing 103 and polluting the RF signals on the center conductor 35.

FIGS. 11 and 12 depict a first alternative embodiment of a receiving chamber 169. The receiving chamber 169 still has a substantially circular cross-sectional shape, when viewed in the plane perpendicular to the central axis CA. The receiving chamber 169 has the first and second RF tabs 127 and 129. The receiving chamber 169 may be viewed as an outer sleeve 169A and an inner sleeve 169B. The inner sleeve 169B is inserted into the outer sleeve 169A, and may be capture within the outer sleeve 169A by rolling, e.g., slightly flattening, first and second ends 171 and 173 of the outer sleeve 169A, or by soldering or an epoxy.

The inner sleeve 169B includes at least one frictional member, such as plural friction tabs 175 formed from its cylindrically shaped wall. FIG. 11 shows sixteen friction tabs 175 formed in two groupings of eight at different sections along the inner sleeve 169B. The friction tabs 175 are formed between through slits cut through the cylindrical wall of the inner sleeve 169B, and are bent inwardly toward the central axis CA of the inner sleeve 169B.

The friction tabs 175 are designed to engage the sidewall of the center conductor 35, as the center conductor 35 is inserted into the receiving chamber 169. As the center conductor 35 passes by the friction tabs 175, the friction tabs 175 are deflected outwardly away from the central axis CA of the inner sleeve 169B, and a good electrical connection is formed between the center conductor 35 and the receiving chamber 169. The receiving chamber 169 may be formed of the same conductive materials as the receiving chamber 121 of the first embodiment. Also, the receiving chamber 169 may be placed inside of the insulating, first and second half shells 137 and 139 and the shield 151, such that the conical shape 149 of the first and second half shells 137 and 139 guide the center conductor 35 into the opening 123 of the receiving chamber 169.

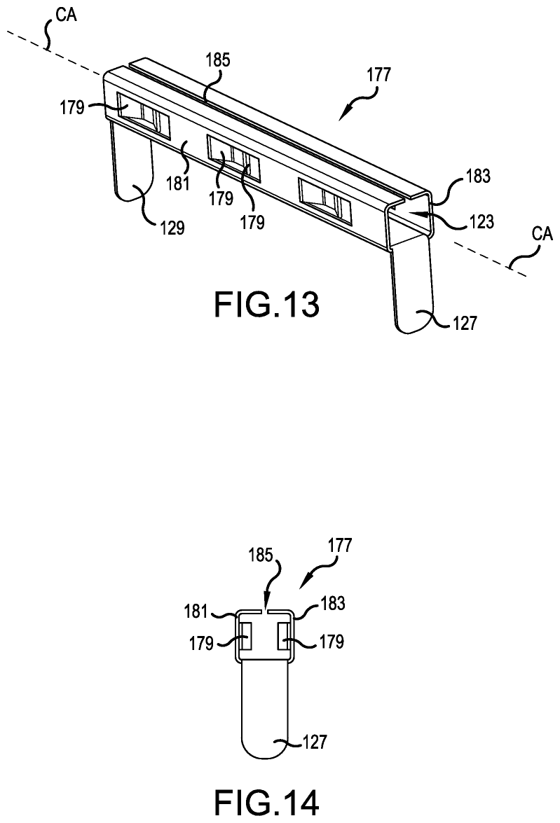

FIGS. 13 and 14 depict a second alternative embodiment of a receiving chamber 177. The receiving chamber 177 has a rectangular, e.g., a square, cross-sectional shape, when viewed in the plane perpendicular to the central axis CA. The receiving chamber 177 has the first and second RF tabs 127 and 129.

The receiving chamber 177 includes at least one frictional member, such as plural friction tabs 179 formed from its side walls. FIGS. 13 and 14 show twelve friction tabs 179 formed in two groupings of six on opposing side walls 181 and 183. Each friction tab 179 is formed between three slits cut through a side wall 181 or 183 and is bent inwardly toward the central axis CA of the receiving chamber 177.

The friction tabs 179 are designed to engage the sidewall of the center conductor 35, as the center conductor 35 is inserted into the receiving chamber 177. As the center conductor 35 passes by the friction tabs 179, the friction tabs 179 are deflected outwardly away from the central axis CA of the receiving chamber 177, and a good electrical connection is formed between the center conductor 35 and the receiving chamber 177. The receiving chamber 177 may be formed of the same conductive materials as the receiving chambers 121 and 169 of the first and second embodiments, and may easily be stamped from a single sheet of metal due to the open slot 185 in the rectangular cross-section of the receiving chamber 177. Also, the receiving chamber 177 may be placed inside of the insulating, first and second half shells 137 and 139 and the shield 151, such that the conical shape 149 of the first and second half shells 137 and 139 guide the center conductor 35 into the opening 123 of the receiving chamber 177.

The circuit board device 119 of the present invention establishes good electrical contact with the center conductor 35 of the male coaxial connector 11, e.g., the stinger, without the use of a seizing member, such as a thread fastener 49 to pinch the center conductor 35 against the conductive surface 43, e.g., the anvil. This allows installers or service technicians to connect a stinger without opening the housing 103 of a ported cable device 101. This reduces the time required for the installation or replacement of equipment. The simpler installation also reduces opportunities for introducing foreign objects into the housing 103. Also, the technician no longer needs to carry a torque measuring tool to seat the threaded fastener 49 and avoids damaging the center conductor 35 due to too much torque and a poor connection due to inadequate torque.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

1. A ported cable device comprising:
an enclosed housing;
a port formed in a wall of said housing, said port having a first cylindrical wall with a conductive inner thread formed on an inner surface of said first cylindrical wall, and a hole communicating an environment, exterior to said housing, with a space within said housing;
a mounting member attached to an interior of said housing, proximate said port; and
a receiving chamber attached to said mounting member, said receiving chamber having an opening aligned with said hole within said port to receive a center conductor of a male coaxial connector which is inserted through said hole in said port, and said receiving chamber also including at least one frictional member formed of a conductive material to frictionally engage and establish an electrical connection to a sidewall of the center conductor of the male connector, wherein when the male connector is connected to said port, the connection is weather-tight.

2. The device according to claim 1, wherein said hole within said port is centered on a central axis of said first cylindrical wall of said port, wherein said first cylindrical wall as an inner diameter of about ⅝ inch, and wherein said inner thread is formed with a pitch of 24 threads per linear inch along a line parallel to said central axis.

3. The device according to claim 1, wherein said mounting member is a circuit board.

4. The device according to claim 3, further comprising:
circuitry forming a filter, surge arrestor, amplifier, splitter, combiner or electrical-to-optical convertor provided on said circuit board and electrically connected to said at least one frictional member.

5. The device according to claim 3, wherein said receiving chamber is tube-like in shape and has a hollow core with said opening formed at one end of said receiving chamber.

6. The device according to claim 5, further comprising:
an insulation material surrounding at least a portion of said receiving chamber; and
an electromagnetic shield surrounding at least a portion of said insulation material.

7. The device according to claim 6, wherein said shield includes plural ground tabs which extend into said circuit board to mechanically secure said shield to said circuit board and to electrically connect said shield to a ground plane of said circuit board.

8. The device according to claim 7, wherein said insulation material is formed as first and second half shells, and wherein said first and second half shells mate to surround said receiving chamber and space said receiving chamber from said shield.

9. The device according to claim 6, wherein the insulation material forms a conical shape to guide the center conductor of the male connector into said opening and said receiving chamber.

10. The device according to claim 5, wherein a cross sectional shape of said receiving chamber is either substantially rectangular or substantially circular.

11. The device according to claim 10, wherein said at least one frictional member includes plural friction tabs formed from a wall or plural walls of said receiving chamber, wherein said friction tabs are bent inwardly to engage the sidewall of the center conductor, as the center conductor is inserted into said receiving chamber.

12. The device according to claim 10, wherein said receiving chamber has at least one expansion fold, and said opening of said receiving chamber has a diameter which is slightly less than a diameter of the center conductor to be inserted into said receiving chamber, and wherein the center conductor expands said opening of said receiving chamber by expanding said at least one expansion fold so as to enlarge said receiving chamber and cause portions of inner sidewalls of said receiving chamber to function as said least one frictional member to frictionally engage, and establish electrical contact with, the outer surface of the center conductor.

13. A circuit board device comprising:
a tube-like receiving chamber with an opening at one end of said receiving chamber, said receiving chamber having at least one frictional member formed of a conductive material to frictionally engage and establish an electrical connection to a sidewall of a center conductor of a male coaxial connector;
a first RF tab for attachment to a mounting member in the form of a circuit board, said first RF tab being electrically connected to said at least one frictional member of said receiving chamber;
an insulation material surrounding at least a portion of said receiving chamber;
an electromagnetic shield surrounding at least a portion of said insulation material, and
plural ground tabs for attachment to the circuit board, each ground tab being electrically connected to said shield.

14. The device according to claim 13, wherein said insulation material is formed as first and second half shells, and wherein said first and second half shells mate to surround said receiving chamber and space said receiving chamber from said shield.

15. The device according to claim 14, wherein said insulation material forms a conical shape to guide the center conductor of the male connector into said opening of said receiving chamber.

16. The device according to claim 13, wherein a cross sectional shape of said receiving chamber is either substantially rectangular or substantially circular.

17. The device according to claim 16, wherein said at least one frictional member includes plural friction tabs formed from a wall or plural walls of said receiving chamber which friction tabs are bent inwardly to engage the sidewall of the center conductor, as the center conductor is inserted into said receiving chamber.

18. The device according to claim 16, wherein said receiving chamber has at least one expansion fold, and said opening of said receiving chamber has a diameter which is slightly less than a diameter of the center conductor to be inserted into said receiving chamber, and wherein the center conductor expands said opening of said receiving chamber by expanding said at least one expansion fold so as to enlarge said receiving chamber and cause portions of inner sidewalls of said receiving chamber to function as said least one frictional member to frictionally engage, and establish electrical contact with, the outer surface of the center conductor.

19. A coaxial connection device comprising:
a ported cable device including:
an enclosed housing;
a port formed in a wall of said housing, said port having a first cylindrical wall with a conductive inner thread formed on an inner surface of said first cylindrical wall, and a hole communicating an environment, exterior to said housing, with a space within said housing;
a mounting member, in the form of a circuit board, attached to an interior of said housing, proximate said port;
a tube-like receiving chamber with an opening at one end of said receiving chamber aligned with said hole within said port to receive a center conductor of a male coaxial connector which is inserted through said hole in said port, said receiving chamber having at least one frictional member formed of a conductive material to frictionally engage and establish an electrical connection to a sidewall of said center conductor of said male coaxial connector;
a first RF tab attached to said circuit board being electrically connected to said at least one frictional member of said receiving chamber;
an insulation material surrounding at least a portion of said receiving chamber;
an electromagnetic shield surrounding at least a portion of said insulation material, and
plural ground tabs attached to said circuit board, each ground tab being electrically connected to said shield; and
said male coaxial connector including:
said center conductor;
a second cylindrical wall having a conductive outer thread formed on an outer surface of said second cylindrical wall; and
a dielectric material between said center conductor and said second cylindrical wall, and wherein said outer thread of said second cylindrical wall is conductively engaged to said inner thread of said first cylindrical wall of said port, and wherein a connection between said male connector and said port is weather-tight.

20. The device according to claim 19, wherein said first cylindrical wall as an inner diameter of about ⅝ inch, and wherein said inner thread is formed with a pitch of 24 threads per linear inch along a line parallel to said central axis.
